(19) United States
(12) Patent Application Publication
(10) Pub. No.: US 2021/0173994 A1
(43) Pub. Date: Jun. 10, 2021

(54) METHOD AND SYSTEM FOR VIEWING SIMULATION SIGNALS OF A DIGITAL PRODUCT

(71) Applicant: Shenzhen State Micro Technology Co., Ltd., Shenzhen (CN)

(72) Inventors: Kaipeng LIN, Shenzhen (CN); Yanrong Li, Shenzhen (CN); Geng Bai, Shenzhen (CN)

(21) Appl. No.: 17/139,323

(22) Filed: Dec. 31, 2020

Related U.S. Application Data
(63) Continuation of application No. PCT/CN2020/081217, filed on Mar. 25, 2020.

(30) Foreign Application Priority Data
Dec. 6, 2019 (CN) 201911243071.3

(51) Int. Cl. G06F 30/343; G06F 30/3312

(52) U.S. Cl. CPC G06F 30/343; G06F 30/3312

(57) ABSTRACT

The present invention discloses a method and system for viewing simulation signals of a digital product. When a controller controls a FPGA to perform a first simulation verification, the controller reads and records status data of all external ports of the digital product in real time, and reads and records all internal status data of the digital product once at each interval. After the FPGA simulation is completed, if data of a certain clock cycle of the digital product needs to be viewed in a backtracking manner, the controller loads the digital product into the software simulator to perform a second simulation verification, and sets the external port status data and the internal status data recorded at said last time point as an initial status of the digital product. By adopting the technical solution, all simulated data of any clock cycle can be viewed quickly in a backtracking manner.

### CROSS-REFERENCE TO RELATED PATENT APPLICATION

This application is a continuation application of International Patent Application

No. PCT/CN2020/081217, filed on Mar. 25, 2020, which itself claims priority to Chinese Patent Application No. CN201911243071.3 filed in China on Dec. 6, 2019. The disclosures of the above applications are incorporated herein in their entireties by reference.

### FIELD

The present invention relates to the field of simulation of digital logic products, in particular to a method and system for viewing simulation signals of a digital product.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In the design process of digital logic products, a simulation verification method is needed to test and verify the correctness of the design. Generally speaking, this link is accomplished using a software simulator.

The working principle of the software simulator is as follows: a design under test (RTL codes or gate-level netlist) and a test vector (hardware description language verification language) (HVL codes or non-synthesizable SystemVerilog program) are operated in the simulator, and a verification process defined in the test vector is completed through the interface signal interaction between the design under test and the test vector. Developers can view a value of any test vector, check a value of any interface or internal signal of the design under test, or check a waveform composed of a plurality of clock cycles to confirm whether the design is correct, and Debug.

However, limited by the software processing performance, the performance of the software simulator is very limited. Generally speaking, to verify a complete design of a system on a chip (SoC), an operating speed may be only tens of Hz. Therefore, in order to speed up, designers tend to migrate the design to a field programmable gate array (FPGA) for verification as soon as possible. This verification method is generally called FPGA Prototyping Verification. The FPGA prototyping verification can reach an operating speed of tens of MHz or even higher, enabling faster verification. However, the FPGA prototyping verification is difficult to detect a signal value of the design under test. A general method is to trigger and display just by guiding a required signal to a port through wiring, and then connecting to a logic analyzer. This detection method is referred to as a static probe. This static probe can only see a very limited number of signals. Each time a new signal needs to be seen, FPGA wiring needs to be re-routed, which requires a long preparation time. Moreover, in this process, due to changes in signals or environment, the original error or event will be difficult to reemerge. Therefore, the debuggability of FPGA is very poor.

In consideration of the obvious advantages and disadvantages of the software simulator and FPGA prototyping verification, the industry tends to a solution that allows the simulation verification process to have the full visibility of signals of the software simulator and the high speed of the FPGA prototyping verification. This solution is referred to as a hardware emulator in the industry. The hardware emulator has two important features:
performance: compared with the software simulator, the hardware emulator has obvious advantages in performance. Generally speaking, the hardware emulator has an operating speed in MHz level; and
signal detectability: compared with the FPGA prototyping verification, the hardware emulator has convenient signal detectability, wherein all internal and port signals of the design under test can be seen, without the need to re-operate or re-configure, which is referred to as “Full Visibility” in terminology.

In order to realize the hardware emulator, there are several technical solutions: a distributed dedicated processor array is adopted, which is equivalent to a super-large-scale processor cluster to operate software simulators in parallel; customized FPGAs are used to form an array, wherein all signals are stored into an external memory through additional signal channels and additional wiring resources; and general-purpose FPGAs are used to form an array, wherein shadow resources are cloned, stored and transferred to an external memory. Alternatively, the signals are read and stored to the external memory by means of the read and write capabilities of a scan chain provided by an FPGA.

The dedicated processor array has the advantage that the signal detectability is very powerful, but has the disadvantages that the operating speed is very slow, the power consumption is very large, and a dedicated processor application-specific integrated circuit (ASIC) needs to be developed, and the upgrade cost is very high. The customized FPGA array has the advantage of high operating speed, but has the disadvantages of the need to invest in the development of a customized FPGA and high upgrade cost. The general-purpose FPGA array has the advantages of high speed and low cost, but the disadvantage of relatively weak signal detectability.

In the solution of the general-purpose FPGA array, there are generally two methods to achieve full signal visibility:

Cloning of shadow resource: all trigger signals of a signal to be tested are output to a shadow register, and then transferred to an external memory one by one through dedicated logic. A combinational signal is calculated from the trigger signals in the later stage through software. This method basically does not reduce the operating speed of the design under test, and consumes a lot of shadow logics, resulting in very low availability of FPGA resources for a logic to be tested (as low as <30%). At the same time, when the signal needs to be displayed after operation, the preparation time for displaying the signal is very long due to the need to recalculate the combinational logic.

Read/write of resources by a FPGA scan chain: all FPGA manufacturers provide read/write channels for internal resources, which can directly read or write logics such as registers (DFF), logic resources (LUT), and built-in SRAM (BRAM) in additional channels outside the ordinary logic resource network (it can be understood as a signal channel from the perspective of God). For example, XILINX calls this function as Configuration Readback Capture. This channel is generally used for FPGA configuration, but the hardware emulator can also use this channel to read any internal signal. This method is referred to as a dynamic probe detection method. The dynamic probe detection method does not any consume FPGA resources. However, because the read channel adopts a manner of serial reading by the scan chain, the speed is extremely slow. If this channel is used for reading, the operating speed is as low as a Hz level. Therefore, the common hardware emulator only uses dynamic probes to obtain respective signal values, and the operating speed will be reduced to an extremely low level when it is used to continuously obtain signals.

### SUMMARY

The present invention aims to provide a method and system for viewing simulation signals of a digital product, which can quickly view all simulation data of any clock cycle in a backtracking manner, in view of the technical problem that the general-purpose FPGA in the above-mentioned related art is low-speed and time-consuming in realizing the full visibility of signals.

In one aspect of the present invention, a simulation system for a digital product is provided, including: a field programmable gate array (FPGA), configured to load the digital product and perform a first simulation verification; a software simulator, configured to perform a second simulation verification on the digital product by software simulation; a controller, configured to control the FPGA to perform a FPGA simulation as the first simulation verification and to control the software simulator to perform the second verification; and a storage device, configured to store simulated data read and recorded by the controller. The controller, when controlling the FPGA to perform the first simulation verification on the digital product, is configured to: read external port status data of all external ports of the digital product in real time, and meanwhile read all internal status data of the digital product once at each interval; and after the FPGA simulation is completed, in response to determining that data of a certain clock cycle of the digital product needs to be viewed in a backtracking manner, read the internal status data of the digital product stored at a last time point before said certain clock cycle and the external port status data at said last time point from the recorded simulated data. The controller, when controlling the software simulator to perform the second simulation verification on the digital product, is configured to load the digital product into the software simulator, set the external port status data and the internal status data recorded at said last time point as an initial status of the digital product, and start the software simulator to operate to the certain clock cycle that needs to be viewed.

In one embodiment of the present invention, the controller, when controlling the FPGA to perform the first simulation verification on the digital product, is further configured to, after reading the external port status data and the internal status data of the digital product, process the external port data and the internal status data of the digital product as ordered structured data with serial numbers of the clock cycles as time stamps, and save the ordered structured data in the storage device.

In one embodiment of the present invention, the controller, when controlling the FPGA to perform the first simulation verification on the digital product, is configured to read the external port status data of all external ports of the digital product using a static probe detection method, and to read all the internal status data of the digital product using a dynamic probe detection method.

In another aspect of the present invention, a method for viewing simulation signals of a digital product is provided, including the following steps:
controlling, by the controller, the FPGA to perform the first simulation verification on the digital product by:
   performing FPGA simulation on the digital product;
   when performing the FPGA simulation, reading and recording the external port status data of all the external ports of the digital product in real time, and reading and recording all the internal status data of the digital product once at each interval; and
   after the FPGA simulation is completed, in response to determining that the data of the certain clock cycle of the digital product needs to be viewed in the backtracking manner, reading the internal status data of the digital product stored at the last time point before said certain clock cycle and the external port status data at said last time point from the recorded simulated data; and
controlling, by the controller, the software simulator to perform the second simulation verification on the digital product by loading the digital product into the software simulator, setting the external port status data and the internal status data recorded at said last time point as the initial status of the digital product, and starting the software simulator to operate to the certain clock cycle that needs to be viewed.

In one embodiment of the present invention, when the external port status data and the internal status data of the digital product are recorded, the external port data and the internal status data of the digital product are saved as ordered structured data with serial numbers of the clock cycles as time stamps.

In one embodiment of the present embodiment, the external port status data of all the external ports of the digital product are read using a static probe detection method.

In one embodiment of the present embodiment, all the internal status data of the digital product are read by using a dynamic probe detection method.

In one embodiment of the present invention, when all the internal status data of the digital product are read once at each interval, an interval time of each interval is identical.

In one embodiment of the present invention, the interval time of each interval is 1 million clock cycles.

In this embodiment of the present invention, when all the internal status data of the digital product are read once at each interval, an interval time of each interval is different.

Compared with the related art, in the simulation signal viewing method and system for the digital product of the present invention, the status data of all external ports of the digital product are read and recorded in real time while performing FPGA simulation on the digital product, and meanwhile all internal status data of the digital product are read and recorded once at each interval; after the simulation is completed, if data of a certain clock cycle of the digital product needs to be viewed in a backtracking manner, the internal status data of the digital product stored at the last time point before said clock cycle and the external port status data at said time point are read from the recorded simulated data, and the digital product is then loaded into the software simulator; the external port status data and the internal status data, which are recorded at said time point, are set as the initial status of the digital product; and the software simulator is started to operate to the clock cycle that needs to be viewed, such that the data of the clock cycle that needs to be viewed can be viewed and recorded by the software simulator. Therefore, the operating time of the FPGA before said time point is shortened, thereby saving the time for viewing data.

### BRIEF DESCRIPTION OF THE DRAWINGS

The following accompanying drawings of the present invention are used here as part of the present invention to understand the present invention. Embodiments of the present invention and their descriptions are shown in the accompanying drawings to explain the principles of the present invention. In the accompanying drawings:

FIG. 1 is a schematic structural diagram of a simulation system for a digital product according to an embodiment of the present disclosure.

FIG. 2 is a flowchart of a method for viewing simulation signals of a digital product according to an embodiment of the present invention.

### DETAILED DESCRIPTION

In order to make the objectives, technical solutions, and advantages of the present invention clearer, the present invention is further described in detail below with reference to the accompanying drawings and embodiments. It should be understood that the specific embodiments described herein are only used to explain the present invention and are not used to limit the present invention.

The term “code”, as used herein, may include software, firmware, and/or microcode, and may refer to programs, routines, functions, classes, and/or objects. The term shared, as used above, means that some or all code from multiple modules may be executed using a single (shared) processor. In addition, some or all code from multiple modules may be stored by a single (shared) memory. The term group, as used above, means that some or all code from a single module may be executed using a group of processors. In addition, some or all code from a single module may be stored using a group of memories.

The term “interface”, as used herein, generally refers to a communication tool or means at a point of interaction between components for performing data communication between the components. Generally, an interface may be applicable at the level of both hardware and software, and may be uni-directional or bi-directional interface. Examples of physical hardware interface may include electrical connectors, buses, ports, cables, terminals, and other I/O devices or components. The components in communication with the interface may be, for example, multiple components or peripheral devices of a computer system.

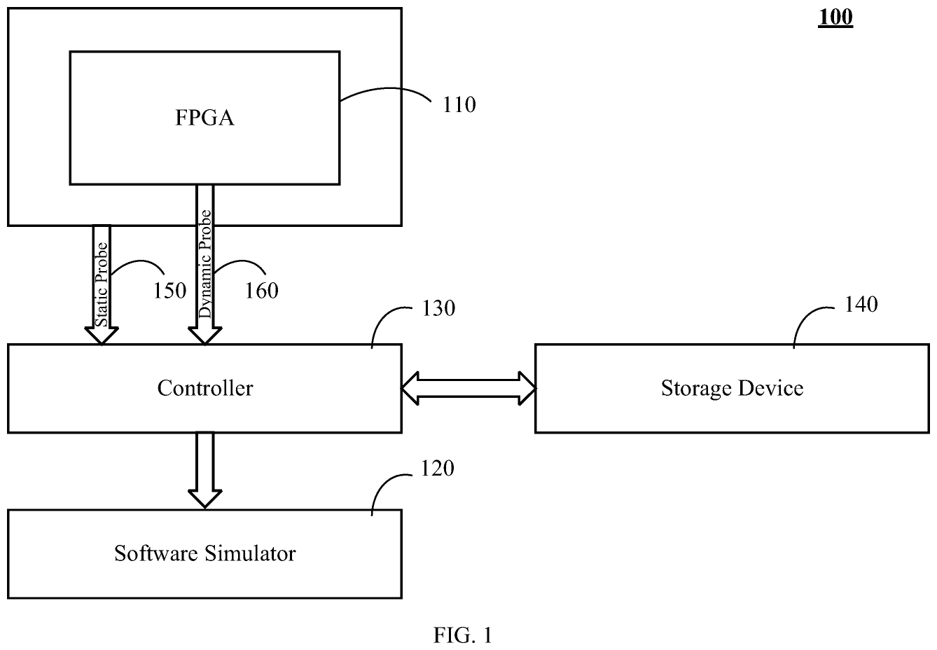

FIG. 1 is a schematic structural diagram of a simulation system for a digital product according to an embodiment of the present disclosure. It should be stated that the system as shown in FIG. 1 only shows schematic components to perform the functions, and, unless otherwise indicated, the components may be implemented or modified by hardware and/or software components or a combination thereof that provide functions.

As shown in FIG. 1, in an embodiment of the present invention, a simulation system 100 for a digital product is provided, which comprises a field programmable gate array (FPGA) 110, a software simulator 120, a controller 130 and a storage device 140. It should be particularly noted that the software simulator 120 and the FPGA 110 are separate components that may be independent operated. In other words, the software simulator 120 does not run on the FPGA 110.

The FPGA 110 is configured to load the digital product and perform FPGA simulation as a first simulation verification. In one embodiment, the FPGA 110 may be a general-purpose FPGA, and the first simulation verification may be a thorough FPGA simulation. However, in an alternative embodiment, the FPGA 110 may also be a customized FPGA or a dedicated FPGA.

The software simulator 120 is configured to perform a second simulation verification on the digital product by means of software simulation. In one embodiment, the second simulation verification may be a partial simulation focusing on a certain clock cycle that needs to be viewed during the first simulation verification.

The controller 130 is configured to control the FPGA 110 to perform FPGA simulation as the first simulation verification and to control the software simulator 120 to perform the second verification, to read the simulation data of the FPGA 110 and the software simulator 120, and to determine whether data of a certain clock cycle of the digital product needs to be viewed.

The storage device 140 is configured to store the simulation data of the FPGA 110. In certain embodiments, the storage device 140 may be a local or a remote storage device. Examples of the storage device 140 may include, without being limited thereto, hard drives, floppy disks, optical drives, non-volatile memory such as flash memory, memory cards, USB drives, or any other types of data storage devices. In certain embodiments, the system 100 may have more than one storage device 140. In the case where multiple storage devices 140 are provided, and the simulation data may be stored in the storage devices 140 separately.

In certain embodiments, when the controller 130 controls the FPGA 110 to perform the first simulation verification on the digital product, the controller 130 may, after reading the external port status data and the internal status data of the digital product, process the external port data and the internal status data of the digital product as ordered structured data with serial numbers of the clock cycles as time stamps, and save the ordered structured data in the storage device 140.

In one embodiment, when the controller 130 controls the FPGA 110 to perform the first simulation verification on the digital product, the controller 130 may read the external port status data of all external ports of the digital product using a static probe detection method 150, and read all the internal status data of the digital product using a dynamic probe detection method 160.

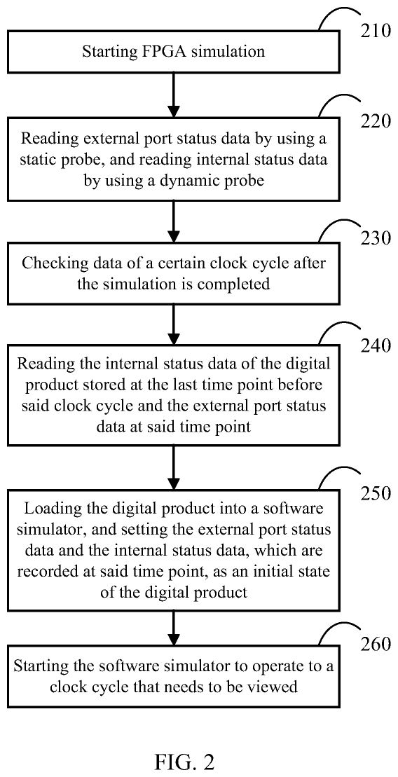

FIG. 2 is a flowchart of a method for viewing simulation signals of a digital product according to an embodiment of the present invention. In certain embodiments, the method as shown in FIG. 2 may be implemented on the simulation system 100 as shown in FIG. 1. It should be particularly noted that, unless otherwise stated in the present invention, the steps of the method may be arranged in a different sequential order, and are thus not limited to the sequential order as shown in FIG. 2.

As shown in FIG. 2, at step 210, the controller 130 controls the FPGA 110 to start performing, as a first simulation verification, FPGA simulation on the digital product. At step 220, when the digital product is subjected to FPGA simulation, the controller 130 reads status data of all external ports of the digital product in real time using a static probe detection method 150, and meanwhile reads all internal status data of the digital product once at each interval using a dynamic probe detection method 160. At the same time, the controller 130 processes the external port data and internal status data of the digital product as ordered structured data using the serial numbers of clock cycles as time stamps, and saves the ordered structured data in the storage device 140. Since the saved data includes the serial numbers of the clock cycles as the time stamps, it is convenient to query data corresponding to a clock cycle when the data is queried subsequently.

It should be noted that when the digital product is subjected to the FPGA simulation, the digital product is loaded into the FPGA 110, and initial operating parameters are then set. When the status data of all external ports of the digital product is read, the external ports have been led out through wires by means of the static probe detection method 150. Therefore, the status data can be read directly in real time without any delay. When all internal status data of the digital product are read, because a read channel adopts a manner of serial reading by a scan chain in the case of using a dynamic probe detection method 160, the speed is extremely slow, and it takes a lot of time to read all internal status data of a digital product every time. Therefore, it is not possible to read all the internal status data of the digital product in real time, and it is also impossible to read it once at a periodic interval.

In one embodiment, when all the internal status data of the digital product are read once at each interval, the interval time of each interval may be identical. For example, the interval time of each interval may be set as 1 million clock cycles. In an alternative embodiment, when all the internal status data of the digital product are read once at each interval, the interval time of each interval may be different. For example, at the beginning of the simulation, the interval time can be set larger, such as 10 million clock cycles. In the later stage of the simulation, the interval time can be set smaller, such as 1 million clock cycles.

At step 230, after the simulation is completed, the controller 130 checks the data to determine if data of a certain clock cycle of the digital product needs to be viewed in a backtracking manner. In response to determining that data of a certain clock cycle of the digital product needs to be viewed in a backtracking manner, at step 240, the controller 130 reads the internal status data of the digital product stored at the last time point before said clock cycle and the external port status data at said last time point from the recorded simulated data.

Once the controller 130 obtains the internal status data of the digital product stored at the last time point before said clock cycle and the external port status data at said last time point from the recorded simulated data, the controller 130 may control the software simulator 120 to start performing a second simulation verification on the digital product. At step 250, the controller 130 controls the software simulator 120 to load the digital product into the software simulator 120; and the external port status data and the internal status data, which are recorded at said last time point, are set as an initial status of the digital product. Then, at step 260, the controller 130 controls the software simulator 120 to start operating to the clock cycle that needs to be viewed, such that the data in the vicinity of the clock cycle that needs to be viewed can be viewed and recorded by the software simulator 120. Therefore, the operating time of the software simulator 120 before said time point is saved, thereby saving the time of viewing data.

In summary, in the simulation signal viewing method and system for the digital product of the present invention, the status data of all external ports of the digital product are read and recorded in real time while performing FPGA simulation on the digital product, and meanwhile all internal status data of the digital product are read and recorded once at each interval; after the simulation is completed, if data of a certain clock cycle of the digital product needs to be viewed in a backtracking manner, the internal status data of the digital product stored at the last time point before said clock cycle and the external port status data at said time point are read from the recorded simulated data; the digital product is then loaded into the software simulator; the external port status data and the internal status data, which are recorded at said time point, are set as the initial status of the digital product; and the software simulator is started to operate to the clock cycle that needs to be viewed, such that the data of the clock cycle that needs to be viewed can be viewed and recorded by the software simulator. Therefore, the operating time of the software simulator before said time point is saved, thereby saving the time of viewing data.

The foregoing descriptions are merely exemplary embodiments of the present disclosure, and are not intended to limit the present invention. Within the spirit and principles of the disclosure, any modifications, equivalent substitutions, improvements, etc., are within the protection scope of the present disclosure.

What is claimed is:

1. A simulation system for a digital product, comprising:
a field programmable gate array (FPGA), configured to load the digital product and perform a first simulation verification;
a software simulator, configured to perform a second simulation verification on the digital product by software simulation;
a controller, configured to control the FPGA to perform a FPGA simulation as the first simulation verification and to control the software simulator to perform the second verification; and
a storage device, configured to store simulated data read and recorded by the controller,
wherein the controller, when controlling the FPGA to perform the first simulation verification on the digital product, is configured to:
read external port status data of all external ports of the digital product in real time, and meanwhile read all internal status data of the digital product once at each interval; and
after the FPGA simulation is completed, in response to determining that data of a certain clock cycle of the digital product needs to be viewed in a backtracking manner, read the internal status data of the digital product stored at a last time point before said certain clock cycle and the external port status data at said last time point from the recorded simulated data;
wherein the controller, when controlling the software simulator to perform the second simulation verification on the digital product, is configured to load the digital product into the software simulator, set the external port status data and the internal status data recorded at said last time point as an initial status of the digital product, and start the software simulator to operate to the certain clock cycle that needs to be viewed.

2. The simulation system according to claim 1, wherein the controller, when controlling the FPGA to perform the first simulation verification on the digital product, is further configured to, after reading the external port status data and the internal status data of the digital product, process the external port data and the internal status data of the digital product as ordered structured data with serial numbers of the clock cycles as time stamps, and save the ordered structured data in the storage device.

3. The simulation system according to claim 1, wherein the controller, when controlling the FPGA to perform the first simulation verification on the digital product, is configured to read the external port status data of all external ports of the digital product using a static probe detection method, and to read all the internal status data of the digital product using a dynamic probe detection method.

4. A method for viewing simulation signals of a digital product using the simulation system according to claim 1, the method comprising the following steps:
controlling, by the controller, the FPGA to perform the first simulation verification on the digital product by:
performing FPGA simulation on the digital product;
when performing the FPGA simulation, reading and recording the external port status data of all the external ports of the digital product in real time, and reading and recording all the internal status data of the digital product once at each interval; and
after the FPGA simulation is completed, in response to determining that the data of the certain clock cycle of the digital product needs to be viewed in the backtracking manner, reading the internal status data of the digital product stored at the last time point before said certain clock cycle and the external port status data at said last time point from the recorded simulated data; and
controlling, by the controller, the software simulator to perform the second simulation verification on the digital product by loading the digital product into the software simulator, setting the external port status data and the internal status data recorded at said last time point as the initial status of the digital product, and starting the software simulator to operate to the certain clock cycle that needs to be viewed.

5. The method according to claim 4, wherein when the external port status data and the internal status data of the digital product are recorded, the external port data and the internal status data of the digital product are saved as ordered structured data with serial numbers of the clock cycles as time stamps.

6. The method according to claim 4, wherein the external port status data of all the external ports of the digital product is read using a static probe detection method. The method according to claim 4, wherein all the internal status data of the digital product are read using a dynamic probe detection method.

8. The method according to claim 4, wherein when all the internal status data of the digital product are read once at each interval, an interval time of each interval is identical.

9. The method according to claim 8, wherein the interval time of each interval is 1 million clock cycles.

10. The method according to claim 4, wherein when all the internal status data of the digital product are read once at each interval, an interval time of each interval is different.
